(19) United States
(12) Patent Application Publication
(10) Pub. No.: US 2025/0241094 A1
(43) Pub. Date: Jul. 24, 2025

(54) MOUNTING SUBSTRATE, LIGHT-EMITTING DEVICE, METHOD OF MANUFACTURING MOUNTING SUBSTRATE, AND METHOD OF MANUFACTURING LIGHT-EMITTING DEVICE

(71) Applicant: NICHIA CORPORATION, Anan-shi (JP)

(72) Inventor: Atsushi HOSOKAWA, Tokushima-shi (JP)

(73) Assignee: NICHIA CORPORATION, Anan-shi (JP)

(21) Appl. No.: 19/023,296

(22) Filed: Jan. 16, 2025

(30) Foreign Application Priority Data
Jan. 19, 2024 (JP) 2024-006716
Oct. 10, 2024 (JP) 2024-178252

(51) Int. Cl. H10H 20/85; H01S 5/02; H01S 5/024; H10H 20/01; H10H 20/857; H10H 20/858

(52) U.S. Cl. CPC H10H 20/8508; H01S 5/0215; H01S 5/02469; H10H 20/021; H10H 20/0364; H10H 20/0365; H10H 20/857; H10H 20/8583; H10H 20/8585

(57) ABSTRACT

A mounting substrate includes a ceramic substrate having two or more through holes, metal members disposed in respective through holes, and a bonding material disposed between the ceramic substrate and each of the metal members in the through holes. A portion of an upper surface, a portion of a lower surface, and a portion of lateral surfaces of each of the metal members are exposed through the ceramic substrate. The portion of the lateral surfaces and the portion of the lower surface of each of the metal members, exposed through the ceramic substrate, are continuous with each other. The portion of the lateral surfaces of each of the metal members, exposed through the ceramic substrate, is coplanar with a lateral surface of the ceramic substrate. The ceramic substrate is disposed so as to surround an outer periphery of each of the metal members in a top view.

### CROSS-REFERENCE TO RELATED APPLICATIONS

The present application claims priority under 35 U.S.C. § 119 to Japanese Patent Application No. 2024-006716, filed Jan. 19, 2024, and Japanese Patent Application No. 2024-178252, filed Oct. 10, 2024, the contents of which are hereby incorporated by reference in their entirety.

### BACKGROUND

### 1. Technical Field

The present disclosure relates to a mounting substrate, a light-emitting device, a method of manufacturing the mounting substrate, and a method of manufacturing the light-emitting device.

### 2. Description of Related Art

For example, Japanese Patent Publication No. 2005-072351 describes a thermal buffer plate in which an electrode member is fitted into an expansion suppressing member. The thermal buffer plate is obtained by preparing the expansion suppressing member made of a ceramic and having a hole penetrating a main surface in a vertical direction and an electrode member made of Cu and having a shape slightly larger than the hole of the expansion suppressing member in the surface direction at room temperature, fitting the electrode member into the hole of the expansion suppressing member, and applying a predetermined temperature.

### SUMMARY

Embodiments of the present disclosure can provide a mounting substrate or a light-emitting device, in which an electronic component can be easily disposed on the mounting substrate through which a metal is exposed. From another viewpoint, embodiments of the present disclosure can provide a mounting substrate having a high heat dissipation property or a light-emitting device including the mounting substrate having a high heat dissipation property.

A mounting substrate according to one embodiment of the present disclosure includes: a ceramic substrate having two or more through holes; metal members disposed in respective through holes; and a bonding material disposed between the ceramic substrate and each of the metal members in the through holes, and configured to bond the ceramic substrate to the metal members. A portion of an upper surface, a portion of a lower surface, and a portion of lateral surfaces of each of the metal members are exposed through the ceramic substrate. The portion of the lateral surfaces and the portion of the lower surface of each of the metal members, exposed through the ceramic substrate, are continuous with each other. The portion of the lateral surfaces of each of the metal members, exposed through the ceramic substrate, is coplanar with a lateral surface of the ceramic substrate. The ceramic substrate is disposed so as to surround an outer periphery of each of the metal members in a top view.

A mounting substrate according to one embodiment of the present disclosure includes: a ceramic substrate having two or more recesses formed in an upper surface; metal members disposed in respective recesses; and a bonding material disposed between the ceramic substrate and each of the metal members in the recesses, and configured to bond the ceramic substrate to the metal members. An upper surface of each of the metal members is exposed through the ceramic substrate. A lower surface of each of the metal members faces a flat surface defining a part of a corresponding one of the two or more recesses of the ceramic substrate.

The light-emitting device according to one embodiment of the present disclosure includes: any of the mounting substrate described above; and a light-emitting element disposed so as to be electrically connected to each of the metal members.

A method of manufacturing a mounting substrate according to one embodiment of the present disclosure includes: preparing a ceramic substrate having two or more through holes or two or more recesses; disposing a bonding material in each of the through holes or the recesses of the ceramic substrate; disposing metal members in respective through holes or respective recesses of the ceramic substrate; and sintering the bonding material disposed in the through holes or in the recesses of the ceramic substrate.

A method of manufacturing a light-emitting device according to one embodiment of the present disclosure includes: preparing a ceramic substrate having two or more through holes or two or more recesses; disposing a bonding material in each of the through holes or in each of the recesses of the ceramic substrate; disposing metal members in respective through holes or in respective recesses of the ceramic substrate; sintering the bonding material disposed in each of the through holes or in each of the recesses of the ceramic substrate; and disposing a light-emitting element such that the light-emitting element is electrically connected to each of the metal members in the ceramic substrate in which the bonding material is sintered.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1 is a schematic perspective view illustrating a mounting substrate according to a first embodiment.

FIG. 2 is a schematic cross-sectional view taken through line II-II of FIG. 1.

FIG. 3 is a flowchart illustrating a method of manufacturing a mounting substrate according to the first embodiment.

FIG. 4 is a schematic perspective view illustrating preparing a ceramic substrate in the method of manufacturing the mounting substrate according to the first embodiment.

FIG. 5 is a schematic cross-sectional view taken through line V-V of FIG. 4.

FIG. 6 is a schematic perspective view illustrating preparing metal members in the method of manufacturing the mounting substrate according to the first embodiment.

FIG. 7 is a schematic cross-sectional view taken through line VII-VII of FIG. 6.

FIG. 8 is a schematic perspective view illustrating disposing a bonding material in the method of manufacturing the mounting substrate according to the first embodiment.

FIG. 9 is a schematic cross-sectional view taken through line IX-IX of FIG. 8.

FIG. 10 is a schematic perspective view illustrating disposing the metal members in the method of manufacturing the mounting substrate according to the first embodiment.

FIG. 11 is a schematic cross-sectional view taken through line XI-XI of FIG. 10.

FIG. 12 is a schematic perspective view illustrating forming a covering part in the method of manufacturing the mounting substrate according to the first embodiment.

FIG. 13 is a schematic cross-sectional view taken through line XIII-XIII of FIG. 12.

FIG. 14 is a schematic cross-sectional view illustrating sintering the bonding material in the method of manufacturing the mounting substrate according to the first embodiment.

FIG. 15 is a schematic perspective view illustrating performing at least one of polishing or grinding on the covering part and the ceramic substrate in the method of manufacturing the mounting substrate according to the first embodiment.

FIG. 16 is a schematic cross-sectional view taken through line XVI-XVI of FIG. 15.

FIG. 17 is a schematic perspective view illustrating singulating a plurality of sets each including a ceramic substrate and metal members in the method of manufacturing the mounting substrate according to the first embodiment.

FIG. 18 is a schematic perspective view illustrating a mounting substrate according to a second embodiment.

FIG. 19 is a schematic cross-sectional view taken through line XIX-XIX of FIG. 18.

FIG. 20 is a flowchart illustrating a method of manufacturing a mounting substrate according to the second embodiment.

FIG. 21 is a schematic perspective view illustrating forming a first metal film by plating in the method of manufacturing the mounting substrate according to the second embodiment.

FIG. 22 is a schematic cross-sectional view taken through line XXII-XXII of FIG. 21.

FIG. 23 is a schematic cross-sectional view illustrating a mounting substrate according to a third embodiment.

FIG. 24 is a flowchart illustrating a method of manufacturing a mounting substrate according to the third embodiment.

FIG. 25 is a schematic cross-sectional view illustrating forming a second metal film by sputtering in the method of manufacturing the mounting substrate according to the third embodiment.

FIG. 26 is a schematic top view illustrating a mounting substrate according to a fourth embodiment.

FIG. 27 is a schematic cross-sectional view taken through line XXVII-XXVII of FIG. 26.

FIG. 28 is a flowchart illustrating a method of manufacturing a mounting substrate according to the fourth embodiment.

FIG. 29 is a schematic cross-sectional view illustrating preparing a ceramic substrate and metal members in the method of manufacturing the mounting substrate according to the fourth embodiment.

FIG. 30 is a schematic cross-sectional view illustrating disposing a bonding material in the method of manufacturing the mounting substrate according to the fourth embodiment.

FIG. 31 is a schematic cross-sectional view illustrating light-emitting devices according to a fifth embodiment.

FIG. 32 is a flowchart illustrating a method of manufacturing a light-emitting device according to the fifth embodiment.

FIG. 33 is a schematic top view illustrating a light-emitting device according to a sixth embodiment.

FIG. 34 is a schematic cross-sectional view taken through line XXXIV-XXXIV of FIG. 33.

### DETAILED DESCRIPTION OF EMBODIMENT

Mounting substrates, light-emitting devices, a method of manufacturing a mounting substrate, and a method of manufacturing a light-emitting device according to embodiments of the present disclosure will be described below with reference to the accompanying drawings. In the following description, terms indicating specific directions and positions (for example, “upper”, “upward”, “lower”, “downward”, and other terms incorporating these terms) are used as necessary. These terms are used to facilitate understanding of the present invention with reference to the drawings, and the technical scope of the present invention is not limited by the meaning of these terms. The same reference numerals appearing in a plurality of drawings refer to the same or similar portions or members.

The embodiments to be described below exemplify the mounting substrates, the light-emitting devices, the method of manufacturing a mounting substrate, and the method of manufacturing a light-emitting device to embody the technical ideas behind the present invention, but the present invention is not limited to the described embodiments. In addition, unless otherwise specified, the dimensions, materials, shapes, relative arrangements, and the like of components described in the embodiments are not intended to limit the scope of the present invention thereto, but are described as examples. The contents described in one embodiment can be applied to other embodiments and modifications. The sizes, positional relationships, and the like of members illustrated in the drawings may be exaggerated for clearer illustration. Furthermore, in order to avoid excessive complication of the drawings, a schematic view in which some portions or elements are not illustrated may be used, or an end view illustrating only a cut surface may be used as a cross-sectional view. Further, “disposing” is not limited to a case of direct contact, but also includes a case of indirectly disposing a member, for example, via another member. The term “height” in the present specification means a position in a direction normal to the upper surface of a ceramic substrate included in each of the mounting substrates according to the embodiments.

### First Embodiment

### Configuration of Mounting Substrate According to First Embodiment

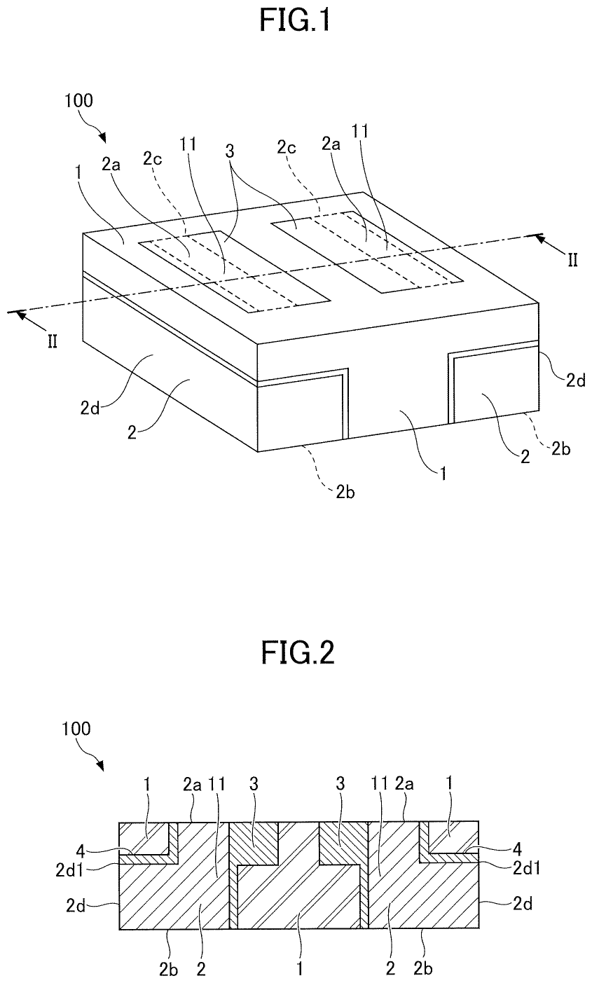

A mounting substrate according to a first embodiment will be described with reference to FIG. 1 and FIG. 2. FIG. 1 is a schematic perspective view illustrating an example of a mounting substrate 100 according to the first embodiment. FIG. 2 is a schematic cross-sectional view taken through line II-II of FIG. 1.

The mounting substrate 100 includes a ceramic substrate 1 having two or more through holes 11, metal members 2 disposed in the respective through holes 11, and a bonding material 3 disposed between the ceramic substrate 1 and each of the metal members 2 in the through holes 11 and configured to bond the ceramic substrate 1 to the metal members 2. An upper surface 2a and a lower surface 2b of each of the metal members 2 are exposed through the ceramic substrate 1, and the ceramic substrate 1 is disposed so as to surround an outer periphery 2c of each of the metal members 2 in a top view.

For example, an electrically-conductive bonding material such as solder or electrically-conductive paste, which is used to mount an electronic component such as a light-emitting element on a mounting substrate, is likely to move on a metal when disposed on the metal. If the electrically-conductive bonding material moves on the metal, exposed through the mounting substrate, when the electrically-conductive bonding material is disposed on the metal, self-alignment of the electronic component or controlling the thickness of the electrically-conductive bonding material would become difficult. If self-alignment of the electronic component and controlling the thickness of the electrically-conductive bonding material cannot be performed, the degree of difficulty to dispose the electronic component on the mounting substrate would increase.

Conversely, in the mounting substrate 100, the ceramic substrate 1 is disposed so as to surround the outer periphery 2c of each of the metal members 2 in a top view. The electrically-conductive bonding material is less likely to move on a ceramic than on a metal. Therefore, by disposing the ceramic substrate 1 so as to surround the outer periphery 2c of each of the metal members 2, the electrically-conductive bonding material disposed on the metal members 2 is unlikely to move. This enables self-alignment of an electronic component to be disposed on the metal and control of the thickness of the electrically-conductive bonding material. In the present embodiment, by enabling self-alignment of the electronic component and control of the thickness of the electrically-conductive bonding material, the electronic component can be easily disposed on the mounting substrate through which the metal is exposed.

In the mounting substrate 100, the bonding material 3 is an active metal brazing material. The active metal brazing material is a brazing material to which active metal powder is added. Examples of an active metal include titanium, zirconium, and hafnium. In the mounting substrate 100, titanium hydride is preferably used as the active metal.

More specifically, the brazing material preferably contains at least one of Ag, Al, Zn, Sn, or an Ag—Cu alloy. The Ag—Cu alloy includes an alloy having a eutectic temperature of approximately 780° C., which is what is known as an Ag—Cu eutectic alloy consisting of about 72% Ag and about 28% Cu. If a brazing material containing the Ag—Cu alloy is used, the brazing material can further contain particles of at least one of Ag, Cu, Cr, or Ni. The melting point of Cu powder is 1,084° C. and the melting point of Ag powder is 962° C., which are much higher than the eutectic temperature of the Ag—Cu alloy. Thus, the Ag powder and the like are not melted at around 780° C. to 850° C. at which the Ag—Cu alloy is melted, and are present in a state of being dispersed in the bonding material 3. Therefore, volume shrinkage of the bonding material 3 can be reduced. Further, the thermal conductivity and the electrical conductivity can be improved by containing the Ag powder, the Cu powder, or the like.

The active metal powder is not particularly limited, and examples of the active metal powder include titanium hydride (TiH₂), cerium hydride (CeH₂), zirconium hydride (ZrH₂), and magnesium hydride (MgH₂). One of these compounds can be used alone or two or more of these compounds can be used in combination. Among them, the active metal powder preferably contains TiH₂. In a case where the active metal powder contains TiH₂, the active metal powder reacts with aluminum nitride exposed at the inner surfaces defining each of the through holes or the like, thereby forming titanium nitride (TiN) as a metal compound. Titanium nitride is known as a barrier metal. Therefore, migration of metals in the bonding material 3 can be suppressed, and a highly reliable ceramic substrate can be obtained.

Further, the active metal brazing material can contain ceramic particles such as silicon nitride or aluminum nitride to the extent that the electrical conductivity is not impaired. By containing the ceramic particles, a difference between the linear expansion coefficient of each of the metal members and the linear expansion coefficient of the ceramic substrate can be minimized. In particular, when the ceramic particles and the ceramic substrate are made of the same material, the difference in linear expansion coefficient can be further minimized, and thus the occurrence of cracks in the metal members and the ceramic substrate can be reduced. The sizes of the metal powder and the ceramic particles contained in the bonding material 3 are smaller than a gap between the ceramic substrate 1 and each of the metal members 2 in the through holes 11.

The linear expansion coefficient of the ceramic substrate differs from the linear expansion coefficient of the metal members. Thus, for example, if the ambient temperature of the mounting substrate changes, a difference in expansion or shrinkage occurs between the ceramic substrate and the metal members. In such a case, there would be a possibility that cracks occur in the mounting substrate. Conversely, the linear expansion coefficient of the active metal brazing material takes a value between the linear expansion coefficient of the ceramic substrate and the linear expansion coefficient of the metal members. Therefore, by disposing the active metal brazing material as the bonding material 3 between the ceramic substrate 1 and each of the metal members 2 in the through holes 11, a difference between the linear expansion coefficient of the ceramic substrate 1 and the linear expansion coefficient of the metal members 2 can be reduced. By reducing the difference between the linear expansion coefficient of the ceramic substrate 1 and the linear expansion coefficient of the metal members 2, even when the ambient temperature of the mounting substrate 100 changes, the occurrence of cracks in the mounting substrate 100 due to the difference between the linear expansion coefficients can be reduced.

In the mounting substrate 100, a portion of lateral surfaces 2d of each of the metal members 2 is exposed through the ceramic substrate 1. For example, not only one lateral surface 2d of the metal member 2 is exposed through the ceramic substrate 1, but three lateral surfaces 2d are exposed through the ceramic substrate 1. Because a portion of lateral surfaces 2d is exposed through the ceramic substrate 1, heat generated in the mounting substrate 100 is transferred through the portion of the lateral surfaces 2d and the lower surface 2b of each of the metal members 2 exposed through the ceramic substrate 1, passes through a bonding material such as solder, and is easily dissipated to the outside of the mounting substrate 100. As a result, the heat dissipation of the mounting substrate 100 can be improved.

The mounting substrate 100 has a stepped surface 4 connected to an upper end 2d1 of a lateral surface 2d of each of the metal members 2 and located below the upper surface 2a of each of the metal members 2. A portion of the ceramic substrate 1 is disposed on the stepped surface 4 connected to each of the metal members 2. For example, each of the metal members 2 has an L-shape in a cross-sectional view corresponding to the line II-II of FIG. 1. As illustrated in FIG. 2, the area of the lower surface 2b is larger than the area of the upper surface 2a of each of the metal members 2.

Because a portion of the ceramic substrate 1 is disposed on the stepped surface 4, the movement of the electrically-conductive bonding material disposed on the stepped surface 4 connected to each of the metal members 2 can be reduced. Thus, self-alignment of an electronic component disposed on the metal members 2 and control of the thickness of the electrically-conductive bonding material can be enabled. In the present embodiment, by enabling self-alignment of the electronic component disposed on the metal members and control of the thickness of the electrically-conductive bonding material, the electronic component can be easily disposed on the mounting substrate through which the metal members are exposed.

As the material of the ceramic substrate 1, a nitride-based ceramic, an oxide-based ceramic, silicon carbide, mullite, borosilicate glass, or the like can be used. Examples of the nitride-based ceramic includes silicon nitride, aluminum nitride, and boron nitride. Examples of the oxide-based ceramic includes aluminum oxide, silicon oxide, calcium oxide, and magnesium oxide. One of these compounds can be used alone or two or more of these compounds can be used in combination. Among them, the nitride-based ceramic is preferably used as a ceramic of the ceramic substrate 1.

As the material of the metal members 2, silver, copper, a silver-copper alloy, a copper-zinc alloy, a copper-tin alloy, or the like can be used. One of these compounds can be used alone or two or more of these compounds can be used in combination. Among them, it is preferable to use copper as the metal material of the metal members 2 in terms of thermal conductivity.

### Method of Manufacturing Mounting Substrate 100

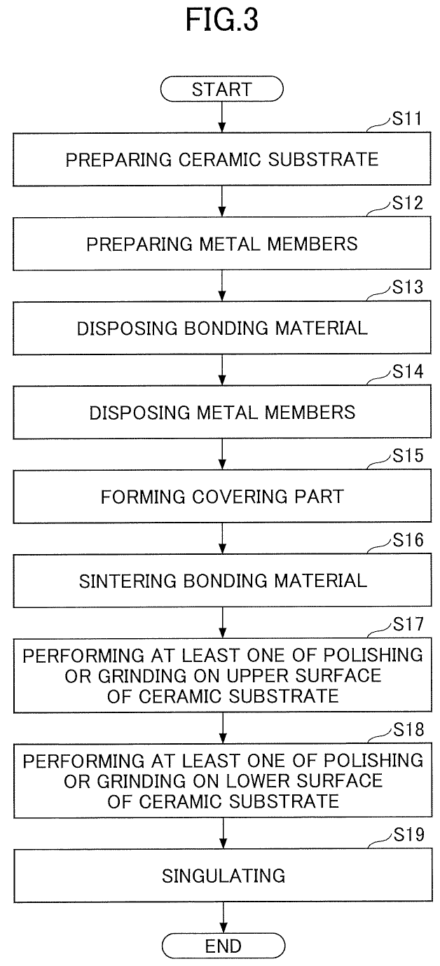

Next, a method of manufacturing a mounting substrate 100 will be described with reference to FIG. 3 to FIG. 17.

FIG. 3 is a flowchart illustrating an example of the method of manufacturing the mounting substrate 100. The method of manufacturing the mounting substrate 100 according to the first embodiment includes preparing a ceramic substrate 1 having two or more through holes 11 or recesses (S11), and disposing a bonding material 3 in each of the through holes 11 or the recesses of the ceramic substrate 1 (S13). Further, the method of manufacturing the mounting substrate 100 includes disposing metal members 2 in the respective through holes 11 or the recesses of the ceramic substrate 1 (S14), and sintering the bonding material 3 disposed in each of the through holes 11 or the recesses of the ceramic substrate 1 (S16).

The method of manufacturing the mounting substrate 100 includes preparing the metal members 2 (S12), and forming an electrically-conductive covering part 5 so as to cover the bonding material 3 and at least one of the upper surface or the lower surface of the ceramic substrate 1 after the bonding material 3 is disposed yet before the bonding material 3 is sintered (S15). Further, the method of manufacturing the mounting substrate 100 includes performing at least one of polishing or grinding on the covering part 5 and the upper surface of the ceramic substrate 1 after the bonding material 3 is sintered so as to expose the metal members 2 (S17). Further, the method of manufacturing the mounting substrate 100 includes performing at least one of polishing or grinding on the covering part 5 and the lower surface of the ceramic substrate 1 after the bonding material 3 is sintered so as to expose the metal members 2 (S18). The mounting substrate 100 includes a plurality of sets each including a ceramic substrate 1 and metal members 2, and the method of manufacturing the mounting substrate 100 includes singulating the plurality of sets (S19).

### S11: Preparing Ceramic Substrate 1

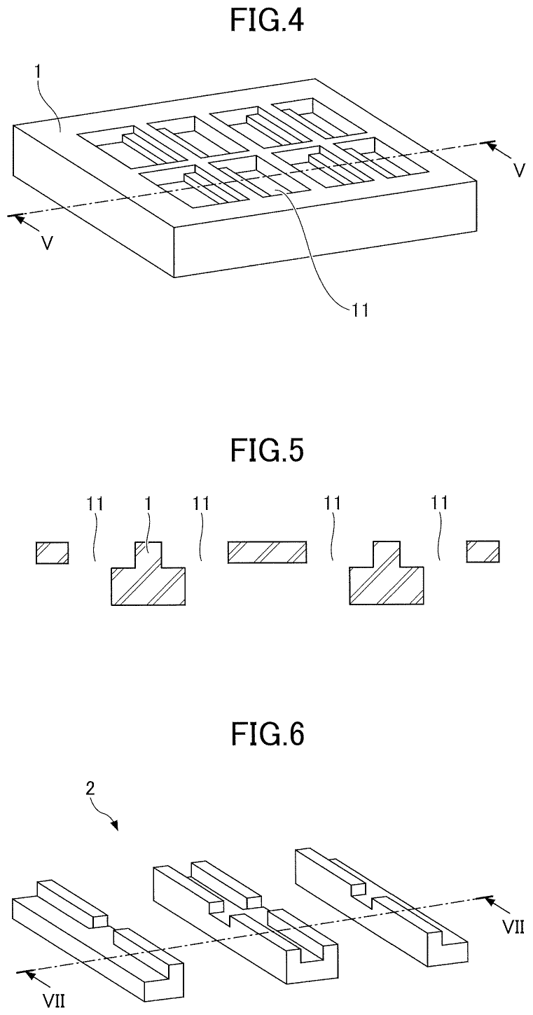

In S11, the ceramic substrate 1 having the two or more through holes 11 is prepared. FIG. 4 is a schematic perspective view illustrating an example of preparing the ceramic substrate 1 in the method of manufacturing the mounting substrate 100. FIG. 5 is a schematic cross-sectional view taken through line V-V of FIG. 4. A plurality of through holes 11 are formed in the ceramic substrate 1. A method of forming the through holes 11 or recesses in the ceramic substrate 1 can be appropriately selected according to the intended shape of the ceramic substrate 1. For example, drilling, laser processing, blasting, etching, or the like can be used. If there is a commercially available product having a desired shape and a desired size as the ceramic substrate 1, preparing the ceramic substrate 1 (S11) can be preparing the commercially available product.

### S12: Preparing Metal Members 2

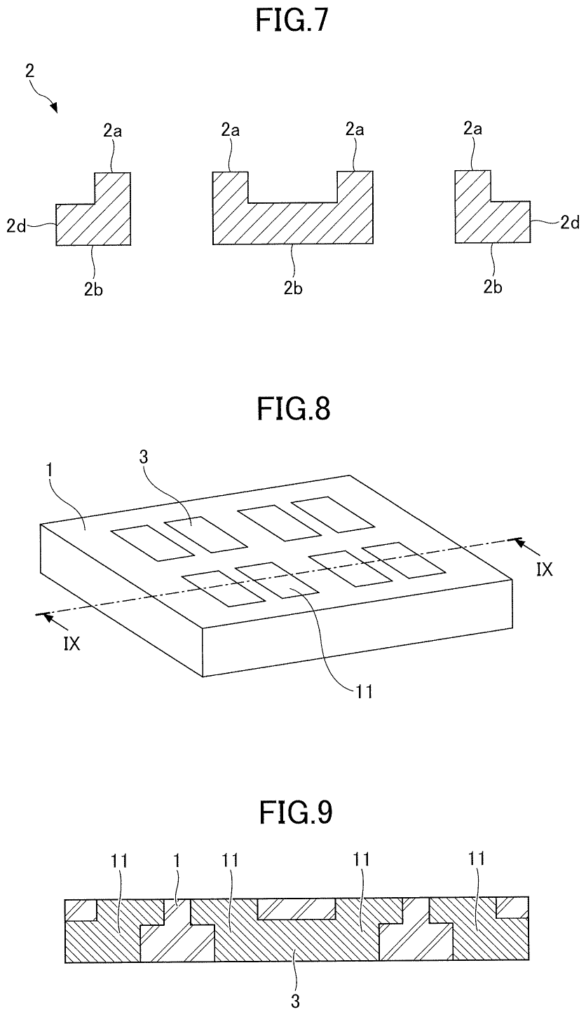

In S12, the metal members 2 are prepared. FIG. 6 is a schematic perspective view illustrating an example of preparing the metal members 2 in the method of manufacturing the mounting substrate 100. FIG. 7 is a schematic cross-sectional view taken through line VII-VII of FIG. 6. The metal members 2 are a plurality of members formed in desired shapes. The metal members 2 are shaped to conform to the shapes of the through holes 11 or the recesses of the ceramic substrate 1. If there are commercially available products having desired shapes and desired sizes as the metal members 2, preparing the metal members 2 (S12) can be preparing the commercially available products.

### S13: Disposing Bonding Material 3

In S13, the bonding material 3 is disposed in each of the through holes 11 or the recesses of the ceramic substrate 1. FIG. 8 is a schematic perspective view illustrating an example of disposing the bonding material 3 in the method of manufacturing the mounting substrate 100. FIG. 9 is a schematic cross-sectional view taken through line IX-IX of FIG. 8. The amount of the bonding material 3 to be applied is preferably adjusted in consideration of volume shrinkage and a difference between the volume of each of the metal members 2, which will be described below, and the volume of each of the through holes 11 or the spaces of the recesses. For example, the amount of the bonding material 3 to be applied can be 0.1% by volume to 30% by volume, preferably 1% by volume to 20% by volume, and particularly preferably 3% by volume to 10% by volume with respect to the difference between the volume of each of the metal members 2, which will be described below, and the volume of each of the through holes 11 or each of the spaces of the recesses.

### S14: Disposing Metal Members 2

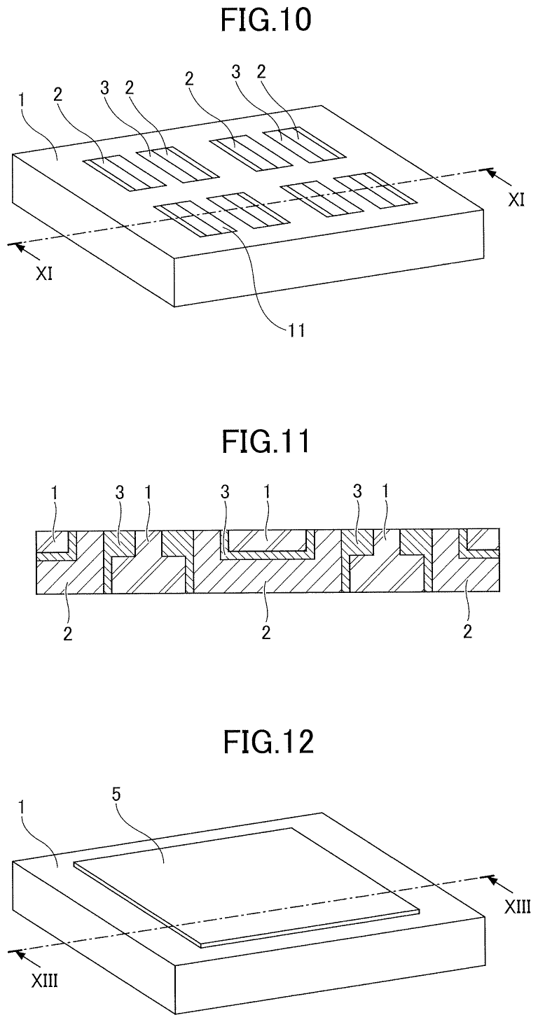

In S14, the metal members 2 are disposed in the respective through holes 11 or the respective recesses of the ceramic substrate 1. FIG. 10 is a schematic perspective view illustrating an example of disposing the metal members 2 in the method of manufacturing the mounting substrate 100. FIG. 11 is a schematic cross-sectional view taken through line XI-XI of FIG. 10. The metal members 2 are disposed at positions corresponding to the through holes 11 or the recesses of the ceramic substrate 1. The metal members 2 can be disposed by being inserted into the ceramic substrate 1 in which the bonding material 3 is disposed in the through holes 11 or the like. Alternatively, the metal members 2 can be disposed by inserting the ceramic substrate 1 having the through holes 11 into the metal members 2 in which the bonding material 3 is disposed. Any bonding material 3 leaking from the through holes 11 can be removed as appropriate, can be spread until flat, or can be disposed to protrude upward in the vicinity of the through holes 11.

### S15: Forming Covering Part 5

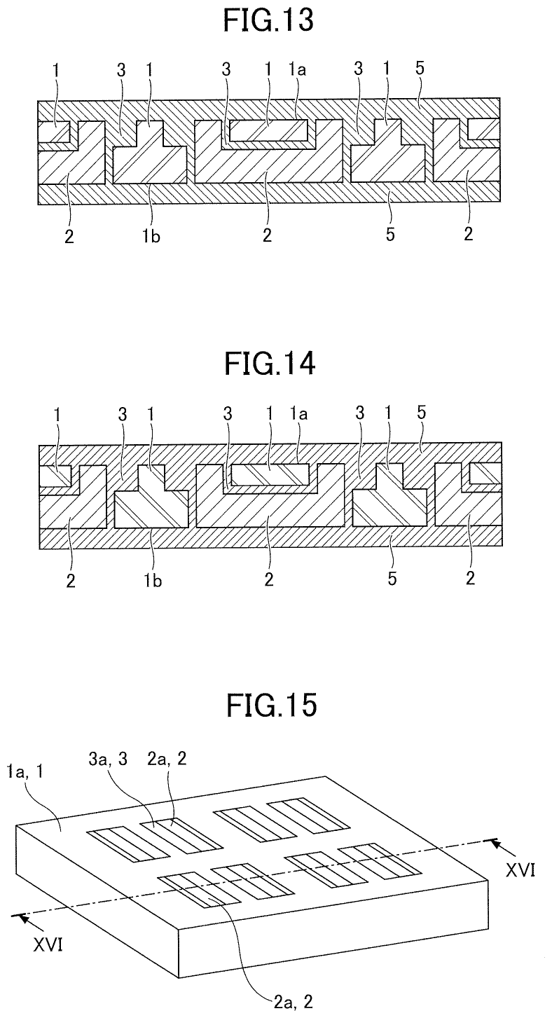

In S15, the electrically-conductive covering part 5 is formed so as to cover the bonding material 3 and at least one of an upper surface 1a or a lower surface 1b of the ceramic substrate 1 after the bonding material 3 is disposed yet before the bonding material 3 is sintered. FIG. 12 is a schematic perspective view illustrating an example of forming the covering part 5 in the method of manufacturing the mounting substrate 100. FIG. 13 is a schematic cross-sectional view taken through line XIII-XIII of FIG. 12. The covering part 5 is formed on the bonding material 3 and each of the upper surface 1a and the lower surface 1b of the ceramic substrate 1.

There may be a case where the bonding material 3 shrinks by being sintered (in S16), which will be described below. If the bonding material 3 shrinks, the height of the upper surface of the sintered bonding material 3 becomes lower than the height of the upper surface 1a of the ceramic substrate 1. In such a case, there would be a possibility that the position of the upper surface of the sintered bonding material 3 and the position of the upper surface 1a of the ceramic substrate 1 are not aligned. Similarly, there would be a possibility that the position of the lower surface of the sintered bonding material 3 and the position of the lower surface 1b of the ceramic substrate 1 are not aligned.

In the method of manufacturing the mounting substrate 100, after the bonding material 3 is disposed yet before the bonding material 3 is sintered, the electrically-conductive covering part 5 is formed so as to cover the bonding material 3 and at least one of the upper surface 1a or the lower surface 1b of the ceramic substrate 1. Accordingly, even if the bonding material 3 shrinks, the possibility that the height of the upper surface of the sintered bonding material 3 becomes lower than the height of the upper surface 1a of the ceramic substrate 1 can be avoided. Therefore, by performing at least one or polishing or grinding on the covering part 5 and the ceramic substrate 1, the height of the upper surface of the sintered bonding material 3 and the height of the upper surface 1a of the ceramic substrate 1 can be aligned. Similarly, the height of the lower surface of the sintered bonding material 3 and the height of the lower surface 1b of the ceramic substrate 1 can be aligned. As the material of the covering part 5, a metal material that is easier to be polished or ground than the ceramic substrate 1 is preferably used.

### S16: Sintering Bonding Material 3

In S16, the bonding material 3 that is placed in each of the through holes 11 or the recesses of the ceramic substrate 1 is sintered. FIG. 14 is a schematic cross-sectional view illustrating an example of sintering the bonding material 3 in the method of manufacturing the mounting substrate 100. The bonding material 3 and the covering part 5 are sintered.

Because the covering part 5 is formed on the bonding material 3 and each of the upper surface 1a and the lower surface 1b of the bonding material 3 and the ceramic substrate 1, even when the bonding material 3 is sintered and shrinks, the height of the upper surface of the sintered bonding material 3 is higher than the height of the upper surface 1a of the ceramic substrate 1. Therefore, by performing at least one of polishing or grinding on the covering part 5 and the ceramic substrate 1, the height of the upper surface of the sintered bonding material 3 and the height of the upper surface 1a of the ceramic substrate 1 can be aligned. From the viewpoint of sintering the bonding material 3 having a melting point lower than the melting point of the metal members 2, the sintering temperature is preferably 700° C. or more and 1,100° C. or less, more preferably 750° C. or more and 900° C. or less, and particularly preferably 780° C. or more and 850° C. or less.

### S17 and S18: Performing At Least One of Polishing or Grinding

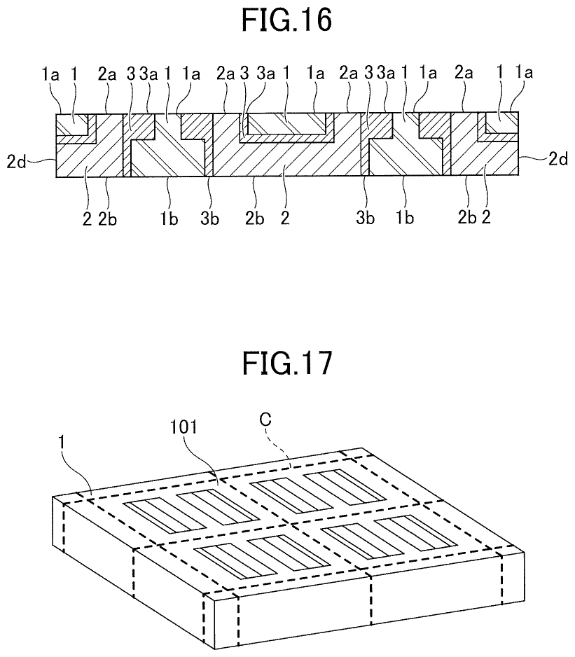

In S17, at least one of polishing or grinding is performed on the covering part 5 and the upper surface 1a of the ceramic substrate 1 after the bonding material 3 is sintered so as to expose the metal members 2. In S18, at least one of polishing or grinding is performed on the covering part 5 and the lower surface 1b of the ceramic substrate 1 after the bonding material 3 is sintered so as to expose the metal members 2. FIG. 15 is a schematic perspective view illustrating an example of performing at least one of polishing or grinding on the covering part 5 and the ceramic substrate 1 in the method of manufacturing the mounting substrate 100. FIG. 16 is a schematic cross-sectional view taken through line XVI-XVI of FIG. 15.

In FIG. 15, in order to indicate that the upper surface 1a of the ceramic substrate 1 and the ceramic substrate 1 overlap each other, the reference numeral of the upper surface 1a of the ceramic substrate 1 is illustrated together with the reference numeral of the ceramic substrate 1. Similarly, in order to indicate that an upper surface 2a of a metal member 2 and the metal member 2 overlap each other, the reference numeral of the upper surface 2a of the metal member 2 is illustrated together with the reference numeral of the metal member 2. In order to indicate that an upper surface 3a of the bonding material 3 and the bonding material 3 overlap each other, the reference numeral of the upper surface 3a of the bonding material 3 is illustrated together with the reference numeral of the bonding material 3. In the following, reference numerals may be illustrated together for a similar purpose.

The upper surface 2a of each of the metal members 2 and the upper surface 3a of the bonding material 3 are exposed through the upper surface 1a of the ceramic substrate 1 by performing at least one of polishing or grinding on the covering part 5 and each of the upper surface 1a and the lower surface 1b of the ceramic substrate 1. The upper surface 3a of the sintered bonding material 3 and the upper surface 1a of the ceramic substrate 1 are coplanar with each other. The term “coplanar” means that there is no step between two surfaces and the two surfaces are in substantially the same positional relationship. The lower surfaces 2b of the metal members 2 and a lower surface 3b of the bonding material 3 are exposed through the lower surface 1b of the ceramic substrate 1. The lower surface 3b of the sintered bonding material 3 and the lower surface 1b of the ceramic substrate 1 are coplanar with each other. Further, a lateral surface of the sintered bonding material 3 and a lateral surface of the ceramic substrate 1 are coplanar with each other. In other words, a portion of the upper surface 2a, a portion of the lower surface 2b, and a portion of the lateral surfaces 2d of each of the metal members 2 are exposed through the ceramic substrate 1. The portion of the lateral surfaces 2d and the portion of the lower surface 2b of each of the metal members 2, exposed through the ceramic substrate 1, are continuous with each other, and the portion of the lateral surfaces 2d of each of the metal members 2, exposed through the ceramic substrate 1, is coplanar with a lateral surface of the ceramic substrate 1.

By cutting the ceramic substrate 1, surfaces are made “coplanar” with each other as described above. In the example illustrated in FIG. 16, the lower surface 2b of each of the metal members 2 is plated, and lateral surfaces 2d that are cut surfaces are not plated. However, the upper surface 2a, the lower surface 2b, and the lateral surfaces 2d of each of the metal members 2 can be plated. When a component is electrically connected to the mounting substrate via an electrically-conductive member such as solder, the electrically-conductive member can be formed continuously not only with the lower surface 2b of each of the metal members 2 but also with lateral surfaces 2d of each of the metal members 2. Accordingly, the heat dissipation is improved as compared to when heat is dissipated from the lower surface 2b of each of the metal members 2.

### S19: Singulating

In S19, a plurality of sets 101 (see FIG. 17) each including a ceramic substrate 1 and metal members 2 are singulated. FIG. 17 is a schematic perspective view illustrating an example of singulating the plurality of sets 101 each including the ceramic substrate 1 and the metal members 2 in the method of manufacturing the mounting substrate 100. The plurality of sets 101 each including the ceramic substrate 1 and the metal members 2 include four sets 101 in which two sets 101 are arranged in each of the widthwise direction and the lengthwise direction. In the method of manufacturing the mounting substrate 100, a plurality of mounting substrates 100 can be obtained from one ceramic substrate 1 by singulating the plurality of sets 101 each including the ceramic substrate 1 and the metal members 2. Accordingly, the manufacturing efficiency of the mounting substrate 100 can be improved.

Cutting lines C indicated by thick dashed lines in FIG. 17 indicate a portion where the ceramic substrate 1 is cut so as to singulate the plurality of sets 101. As a cutting method of singulating the plurality of sets, for example, a method using a rotation blade having a disk shape, an ultrasonic cutter, laser light irradiation, a blade, or the like can be applied. By singulating the plurality of sets 101, the four sets 101 each including the ceramic substrate 1 and the metal members 2 can be obtained. In the singulating of the plurality of sets (S19), a portion of lateral surfaces 2d of each of the metal members 2, exposed through the ceramic substrate 1, is preferably coplanar with a lateral surface of the ceramic substrate 1.

### Second Embodiment

### Configuration of Mounting Substrate According to Second Embodiment

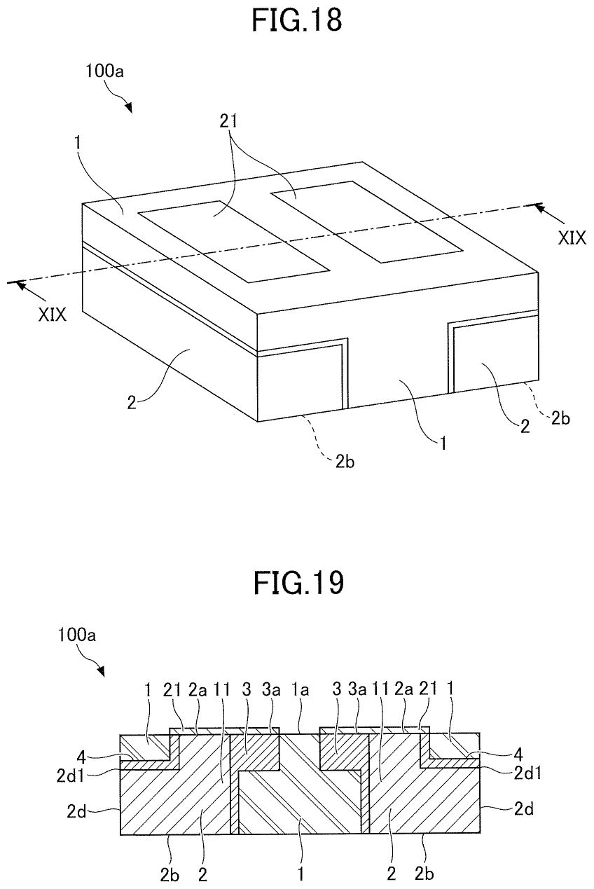

A mounting substrate according to a second embodiment will be described with reference to FIG. 18 and FIG. 19. FIG. 18 is a schematic perspective view illustrating an example of a mounting substrate 100a according to the second embodiment. FIG. 19 is a schematic cross-sectional view taken through line XIX-XIX of FIG. 18.

The mounting substrate 100a according to the second embodiment differs from the mounting substrate 100 according to the first embodiment mainly in that a metal film 21 is disposed on an upper surface 2a of each of metal members 2. The metal film 21 can be disposed not only on the upper surface 2a of each of the metal members 2 but also on an upper surface 3a of a bonding material 3.

In the mounting substrate 100a, for example, as compared to the upper surface 2a of each of the metal members 2 before the metal film 21 is disposed, the metal film 21 exhibiting good wettability to an electrically-conductive bonding material, which is used when an electronic component such as a light-emitting element is mounted on the mounting substrate 100a, can be disposed on the upper surface 2a of each of the metal members 2 and the upper surface 3a of the bonding material 3. Accordingly, when the electrically-conductive bonding material is disposed on the metal members 2, the wettability of the electrically-conductive bonding material on the metal members 2 can be improved. In addition, because the wettability of the electrically-conductive bonding material is improved, a good connection can be established between each of the metal members 2 and an external circuit component, wiring, or the like.

Further, in the mounting substrate 100a, for example, as compared to the upper surface 2a of each of the metal members 2 before the metal film 21 is disposed, the metal film 21 exhibiting a high reflectance to light emitted from a light-emitting element can be disposed on the upper surface 2a of each of the metal members 2. Accordingly, when the light-emitting element is mounted on the mounting substrate 100a, the reflectance of the metal members 2 with respect to the light emitted from the light-emitting element can be increased, and thus the light extraction efficiency of a light-emitting device including the light-emitting element and the mounting substrate 100a can be increased.

For the metal film 21, a material such as nickel, palladium, aluminum, silver, or gold can be used.

### Method of Manufacturing Mounting Substrate 100a

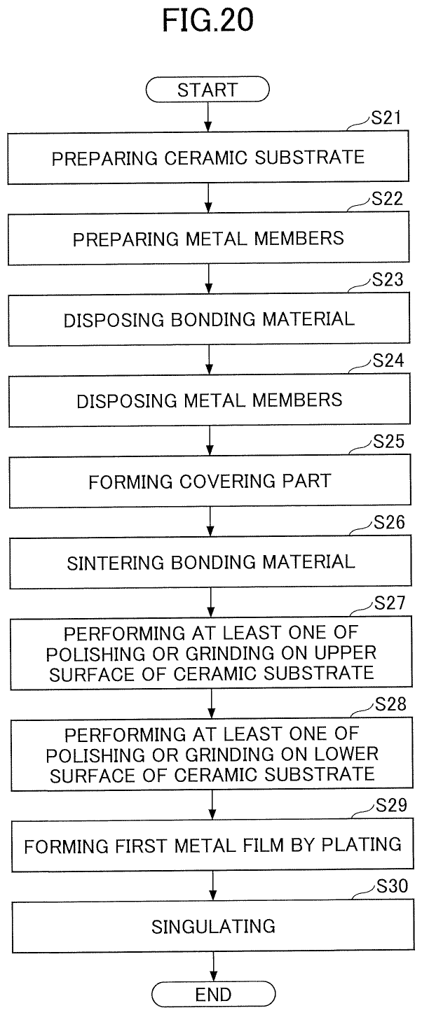

A method of manufacturing a mounting substrate 100a according to the second embodiment will be described with reference to FIG. 20 to FIG. 22.

FIG. 20 is a flowchart illustrating an example of the method of manufacturing the mounting substrate 100a. The method of manufacturing the mounting substrate 100a according to the second embodiment differs from the method of manufacturing the mounting substrate 100 according to the first embodiment mainly in that the method of manufacturing the mounting substrate 100a includes forming, by plating, a first metal film 211 on upper surfaces 2a of metal members 2 in a ceramic substrate 1 subjected to at least one of polishing or grinding (S29). The first metal film 211 is an example of the metal film 21.

S21 to S28 and S30 in the method of manufacturing the mounting substrate 100a according to the second embodiment are the same as S11 to S18 and S20 in the method of manufacturing the mounting substrate 100 according to the first embodiment.

S29: Forming First Metal film 211 by Plating

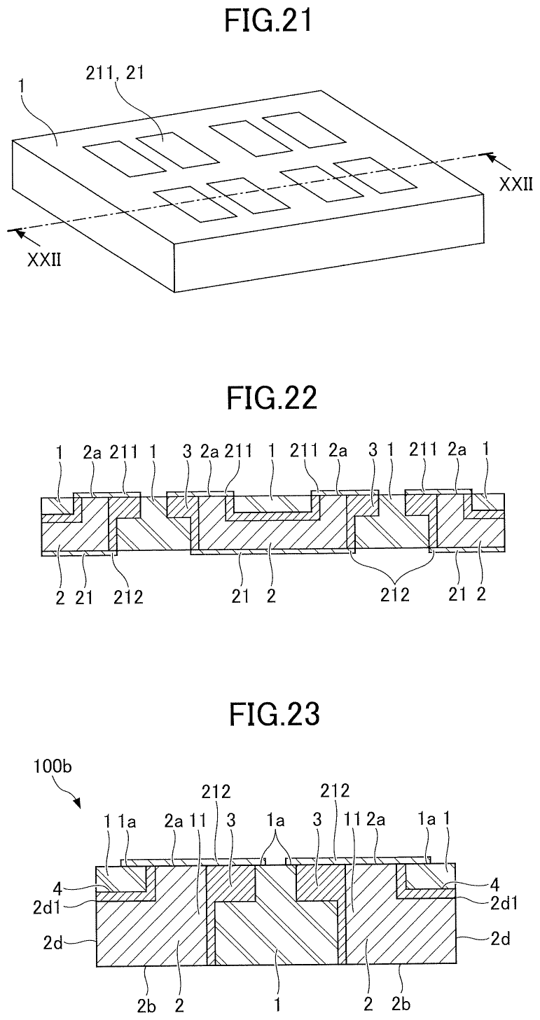

In S29, the first metal film 211 is formed by plating on the upper surfaces 2a of the metal members 2 in the ceramic substrate 1 subjected to at least one of polishing or grinding in S28. The first metal film 211 is also formed on the upper surface 3a of the bonding material 3 by plating. FIG. 21 is a schematic perspective view illustrating an example of forming the first metal film 211 by plating in the method of manufacturing the mounting substrate 100a. FIG. 22 is a schematic cross-sectional view taken through line XXII-XXII of FIG. 21. In the example illustrated in FIG. 21, in order to indicate that the first metal film 211 is an example of the metal film 21, the reference numeral of the first metal film 211 is illustrated together with the reference numeral of the metal film 21.

In the example illustrated in FIG. 21 and FIG. 22, the first metal film 211 is formed by plating on a plurality of portions of the upper surfaces 2a of the metal members 2, which are exposed through the ceramic substrate 1. In addition, a second metal film 212 is formed by plating on a plurality of portion of lower surfaces 2b of the metal members 2, which are exposed through the ceramic substrate 1. The first metal film 211 and the second metal film 212 can be formed by, for example, electrolytic plating or electroless plating. Plating can be performed through a mask. The first metal film 211 and the second metal film 212 protrude from the ceramic substrate 1 by the thickness of the plating. However, protrusions of the first metal film 211 and the second metal film 212 from the ceramic substrate 1 can be reduced by being subjected to pressing after the plating. The thickness of each of the first metal film 211 and the second metal film 212 is not particularly limited, and is preferably 0.5 μm or more and 50 μm or less, and particularly preferably 1 μm or more and 30 μm or less.

### Third Embodiment

### Configuration of Mounting Substrate According to Third Embodiment

A mounting substrate according to a third embodiment will be described with reference to FIG. 23. FIG. 23 is a schematic cross-sectional view illustrating an example of a mounting substrate 100b according to the third embodiment.

The mounting substrate 100b according to the third embodiment differs from the mounting substrate 100 according to the first embodiment mainly in that a second metal film 212 extends from an upper surface 2a of each of metal members 2 to an upper surface 3a of a bonding material 3 and to a portion of an upper surface 1a of a ceramic substrate 1.

In the mounting substrate 100b, the second metal film 212 extends from the upper surface 2a of each of the metal members 2 to the upper surface 3a of the bonding material 3 and to a portion of the upper surface 1a of the ceramic substrate 1, and thus a region of a metal portion can be made wider than that of the mounting substrate 100. In the mounting substrate 100b, as compared to the mounting substrate 100, a metal film 21 exhibiting good wettability to an electrically-conductive bonding material, which is used when an electronic component such as a light-emitting element is mounted on the mounting substrate 100b, can be disposed so as to extend from the upper surface 2a of each of the metal members 2 to the upper surface 3a of the bonding material 3 and to a portion of the upper surface 1a of the ceramic substrate 1. Accordingly, when the electrically-conductive bonding material is disposed on the upper surface 2a of each of the metal members 2, the wettability of the electrically-conductive bonding material on the metal members 2 can be improved. By increasing a region where the wettability of the electrically-conductive bonding material is good, a good connection can be established between each of the metal members 2 and an external circuit component, wiring, or the like.

Further, in the mounting substrate 100b, for example, as compared to the upper surface 2a of each of the metal members 2 before the metal film 21 is disposed, the metal film 21 exhibiting a high reflectance to light emitted from a light-emitting element can be disposed on the upper surface 2a of each of the metal members 2 and the like. Accordingly, as compared to the upper surface 2a of each of the metal members 2 before the metal film 21 is disposed, a region of each of the metal members 2 having a high reflectance to the light emitted from the light-emitting element can be widened.

### Method of Manufacturing Mounting Substrate 100b

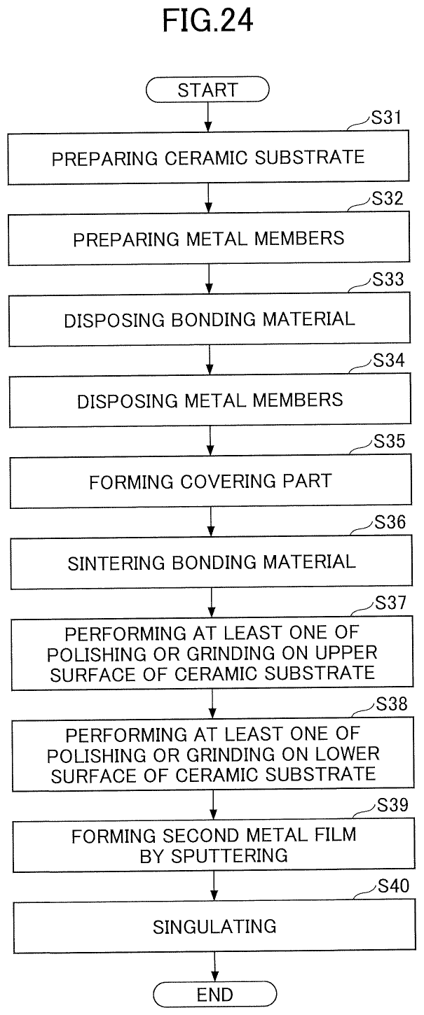

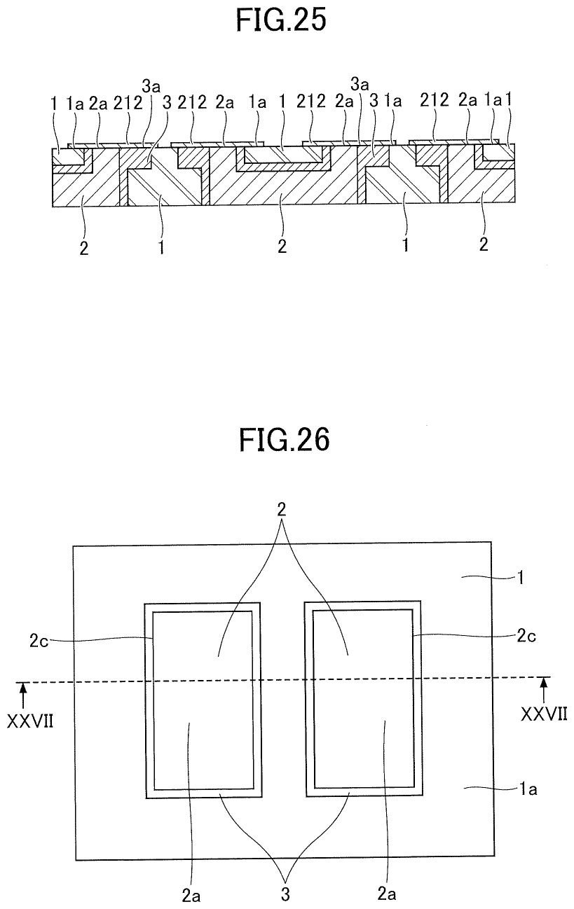

A method of manufacturing a mounting substrate 100b according to the third embodiment will be described with reference to FIG. 24 and FIG. 25.

FIG. 24 is a flowchart illustrating an example of the method of manufacturing the mounting substrate 100b. The method of manufacturing the mounting substrate 100b according to the third embodiment differs from the method of manufacturing the mounting substrate 100 according to the first embodiment mainly in that the method of manufacturing the mounting substrate 100b includes forming, by sputtering, a second metal film 212 on an upper surface 1a of a ceramic substrate 1 subjected to at least one of polishing or grinding. The second metal film 212 is an example of the metal film 21.

S31 to S38 and S40 in the method of manufacturing the mounting substrate 100b according to the third embodiment are the same as S11 to S18 and S20 in the method of manufacturing the mounting substrate 100 according to the first embodiment.

### S39: Forming Second Metal Film 212 by Sputtering

In S39, the second metal film 212 is formed by sputtering on upper surfaces 2a of metal members 2 in the ceramic substrate 1 subjected to at least one of polishing or grinding in S38. The second metal film 212 is also formed on an upper surface 3a of a bonding material 3 and a portion of the upper surface 1a of the ceramic substrate 1 by sputtering. FIG. 25 is a schematic cross-sectional view illustrating an example of forming the second metal film 212 by sputtering in the method of manufacturing the mounting substrate 100b. FIG. 25 illustrates a cross section corresponding to the cross section of the line XXII-XXII of FIG. 21.

In the example illustrated in FIG. 25, the second metal film 212 is formed by sputtering on a plurality of portions of the upper surfaces 2a of the metal members 2 exposed through the ceramic substrate 1, the upper surface 3a of the bonding material 3, and a portion of the upper surface 1a of the ceramic substrate 1.

The method of manufacturing the mounting substrate 100b can include forming, by plating, a first metal film 211 on the second metal film 212 formed by sputtering. By forming the first metal film 211 on the second metal film 212, a metal film 21 having a thickness of about several μm to several tens of μm, which is thicker than a metal film 21 having a thickness of about several μm formed by sputtering, can be formed. By increasing the thickness of the metal film 21, the reflectance of light emitted from a light-emitting element can be increased when the light-emitting element is mounted, and the light extraction efficiency of a light-emitting device including the light-emitting element and the mounting substrate 100b can be increased. Further, by forming the first metal film 211 on the second metal film 212, a region where the first metal film 211 can be formed can be widened.

### Fourth Embodiment

### Configuration of Mounting Substrate According to Fourth Embodiment

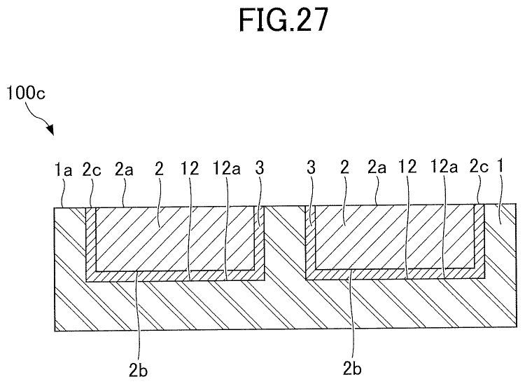

A mounting substrate according to a fourth embodiment will be described with reference to FIG. 26 and FIG. 27. FIG. 26 is a schematic top view illustrating an example of a mounting substrate 100c according to the fourth embodiment. FIG. 27 is a schematic cross-sectional view taken through line XXVII-XXVII of FIG. 26.

The mounting substrate 100c according to the fourth embodiment includes a ceramic substrate 1 having two or more recesses 12 formed in an upper surface 1a of the ceramic substrate 1, metal members 2 disposed in the respective recesses 12, and a bonding material 3 disposed between the ceramic substrate 1 and each of the metal members 2 in the recesses 12 and configured to bond the ceramic substrate 1 to the metal members 2. An upper surfaces 2a of each of the metal members 2 is exposed through the ceramic substrate 1, and a lower surfaces 2b of each of the metal members 2 faces a flat surface 12a defining a part of a corresponding one of the two or more recesses 12 of the ceramic substrate 1. From another viewpoint, the mounting substrate 100c differs from the mounting substrate 100 according to the first embodiment in that the mounting substrate 100c includes the ceramic substrate 1 having the recesses 12, instead of the through holes 11 of the first embodiment. Each of the metal members 2 of the mounting substrate 100c is a block body.

With a configuration in which the mounting substrate 100c includes the ceramic substrate 1 having the recesses 12, the ceramic substrate 1 disposed to surround an outer periphery 2c of each of the metal members 2 can reduce the movement of an electrically-conductive bonding material disposed on the metal members 2. With this configuration, self-alignment of an electronic component disposed on a metal and control of the thickness of the electrically-conductive bonding material can be enabled. In the present embodiment, by enabling self-alignment of the electronic component disposed on the metal and control of the thickness of the electrically-conductive bonding material, the electronic component can be easily disposed on the mounting substrate through which the metal is exposed. In addition, when the ceramic substrate 1 has the recesses 12, an effect of reducing leakage of the bonding material 3 can be obtained. Further, because each of the metal members 2 is a block body, the metal members 2 can be easily disposed in the respective recesses 12, and the mounting substrate 100c can be easily manufactured.

### Method of Manufacturing Mounting Substrate 100c

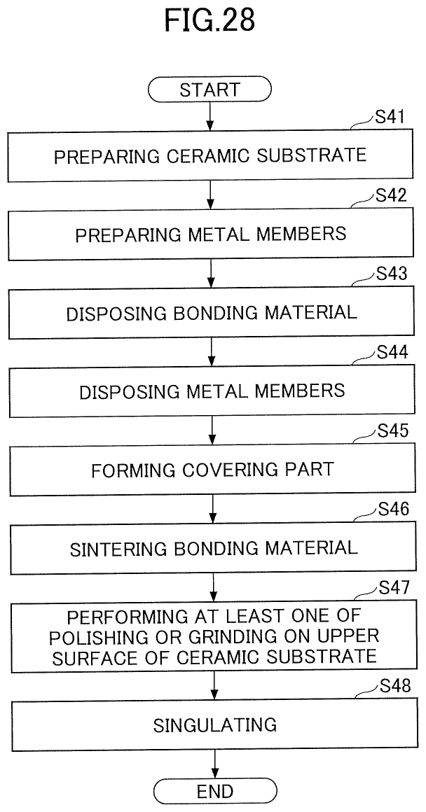

An example of a method of manufacturing a mounting substrate 100c will be described with reference to FIG. 28 to FIG. 30.

FIG. 28 is a flowchart illustrating the method of manufacturing the mounting substrate 100c according to the fourth embodiment. The method of manufacturing the mounting substrate 100c according to the fourth embodiment includes preparing a ceramic substrate 1 having two or more recesses 12 (S41), and disposing a bonding material 3 in each of the recesses 12 of the ceramic substrate 1 (S43). The method of manufacturing the mounting substrate 100c further includes disposing metal members 2 in the respective recesses 12 of the ceramic substrate 1 (S44), and sintering the bonding material 3 disposed in each of the recesses 12 of the ceramic substrate 1 (S46).

The method of manufacturing the mounting substrate 100c includes preparing the metal members 2 (S42), and forming an electrically-conductive covering part 5 so as to cover the bonding material 3 and at least one of the upper surface or the lower surface of the ceramic substrate 1 after the bonding material 3 is disposed yet before the bonding material 3 is sintered (S45). The method of manufacturing the mounting substrate 100c further includes performing at least one of polishing or grinding on the covering part 5 and the upper surface of the ceramic substrate 1 after the bonding material 3 is sintered so as to expose the metal member 2 (S47). The mounting substrate 100c includes a plurality of sets each including a ceramic substrate 1 and metal member 2, and the method of manufacturing the mounting substrate 100c includes singulating the plurality of sets (S49).

In the following, differences from the flowchart illustrating the method of manufacturing the mounting substrate 100 according to the first embodiment as illustrated in FIG. 3 will be mainly described.

### S41: Preparing Ceramic Substrate 1 and S42: Preparing Metal Member 2

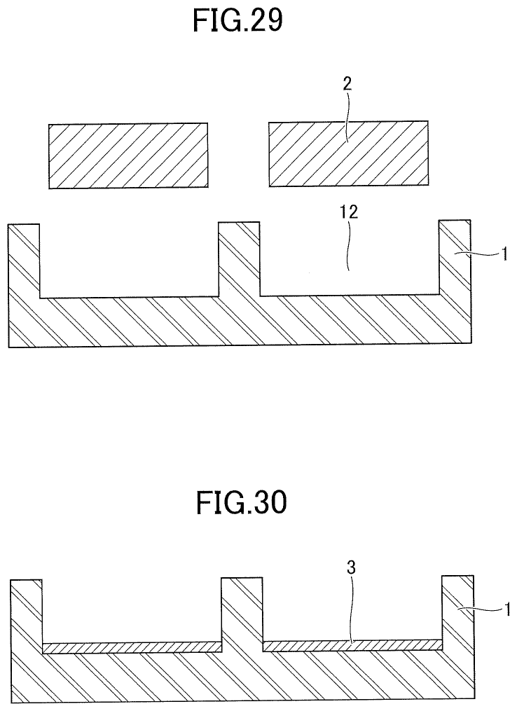

In S41, the ceramic substrate 1 having the two or more recesses 12 is prepared. In S42, the metal members 2 are prepared. FIG. 29 is a schematic cross-sectional view illustrating an example of preparing the ceramic substrate 1 and preparing the metal members 2 in the method of manufacturing the mounting substrate 100c. A plurality of recesses 12 are formed in the ceramic substrate 1. A method of forming the recesses 12 in the ceramic substrate 1 can be appropriately selected according to the intended shape of the ceramic substrate 1. For example, drilling, laser processing, blasting, etching, or the like can be used. If there is a commercially available product having a desired shape and a desired size as the ceramic substrate 1, preparing the ceramic substrate 1 (S41) can be preparing the commercially available product. In addition, if there are commercially available products having desired shapes and desired sizes as the metal members 2, preparing the metal members 2 (S42) can be preparing the commercially available products.

### S43: Disposing Bonding Material 3

In S43, the bonding material 3 is disposed in each of the recesses 12 formed in the ceramic substrate 1. FIG. 30 is a schematic cross-sectional view illustrating an example of disposing the bonding material 3 in the method of manufacturing the mounting substrate 100c according to the fourth embodiment.

S47: Performing At least One of Polishing or Grinding on Upper Surface 1a of Ceramic Substrate 1

In S47, at least one of polishing or grinding is performed on the covering part 5 and the upper surface 1a of the ceramic substrate 1 after the bonding material 3 is sintered so as to expose the metal member 2. In the method of manufacturing the mounting substrate 100c, the lower surface 1b of the ceramic substrate 1 is not polished and ground.

### Fifth Embodiment

### Configuration of Light-Emitting Device According to Fifth Embodiment

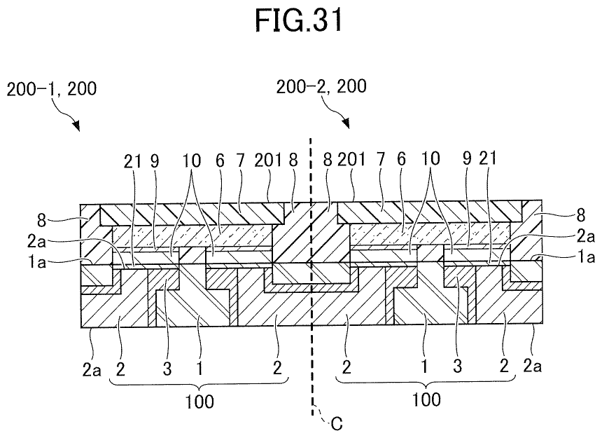

A light-emitting device according to a fifth embodiment will be described with reference to FIG. 31. FIG. 31 is a schematic cross-sectional view illustrating an example of light-emitting devices 200 according to the fifth embodiment. FIG. 31 illustrate two light-emitting devices 200, that is, a light-emitting device 200-1 and a light-emitting device 200-2 before being singulated by cutting along a cutting line C.

A light-emitting device 200 includes a mounting substrate 100 and a light-emitting element 6 disposed so as to be electrically connected to each of metal members 2. In the example illustrated in FIG. 31, the light-emitting device 200 includes a light transmissive member 7 disposed on the light-emitting element 6, a light reflecting member 8 disposed around each of the light-emitting element 6 and the light transmissive member 7, a pair of electrodes 9 disposed on metal films 21, and an electrically-conductive bonding material 10 configured to bond the pair of electrodes 9 to the light-emitting element 6.

Because the light-emitting device 200 includes the mounting substrate 100, the movement of the electrically-conductive bonding material disposed on the metal members 2 can be reduced. As a result, self-alignment of an electronic component disposed on the metal and control of the thickness of the electrically-conductive bonding material can be enabled. In the present embodiment, by enabling self-alignment of the electronic component disposed on the metal and control of the thickness of the electrically-conductive bonding material, the light-emitting element 6 can be easily disposed on the mounting substrate through which the metal is exposed, and the light-emitting device 200 can be easily manufactured. The light-emitting device 200 can include any one of the mounting substrate 100, the mounting substrate 100a, or the mounting substrate 100b.

The light-emitting device 200 is a device in which the light-emitting element 6 is disposed on the mounting substrate 100 and light can be emitted from the light-emitting element 6. The light-emitting device 200 can emit light from a light emitting surface 201 in a direction in which the light emitting surface 201 faces. The number of light-emitting elements 6 included in one light-emitting device 200 is not limited to one, and a plurality of light-emitting elements 6 can be included. If the light-emitting device 200 includes a plurality of light-emitting elements 6, the arrangement of the plurality of light-emitting elements 6 is not particularly limited. Whether to arrange the plurality of light-emitting elements 6 in one axial direction, in two axial directions, or the like can be selected as appropriate according to the application of the light-emitting device 200.

In the mounting substrate 100, wiring can be formed in various patterns according to the application. The light-emitting device 200 includes the pair of electrodes 9 on the same surface side of the light-emitting element 6. The light-emitting device 200 is face-down mounted, with the surface provided with the pair of electrodes 9 facing upper surfaces 2a of the metal members 2 of the mounting substrate 100. Each component of the light-emitting device 200 will be described in detail below.

### Light-Emitting Element 6

The light-emitting element 6 includes various semiconductors such as group III-V compound semiconductors and group II-VI compound semiconductors. As the semiconductors, nitride-based semiconductors such as In_{X}Al_{Y}Ga_{1-X-Y}N (0≤X, 0≤Y, X+Y≤1) are preferably used, and InN, AlN, GaN, InGaN, AlGaN, InGaAlN, and the like can also be used. The light-emitting element 6 is, for example, a light-emitting diode (LED) or a laser diode (LD). The emission peak wavelength of the light-emitting element 6 is preferably 400 nm or more and 530 nm or less, more preferably 420 nm or more and 490 nm or less, and even more preferably 450 nm or more and 475 nm or less, from the viewpoint of emission efficiency, excitation of a wavelength conversion substance, and the like.

### Light Transmissive Member 7

The light transmissive member 7 is a member having, for example, a substantially rectangular shape in a top view. The light transmissive member 7 is disposed so as to cover the upper surface of the light-emitting element 6. In the example illustrated in FIG. 31, the upper surface of the light transmissive member 7 corresponds to the light emitting surface 201. The light transmissive member 7 preferable contains a wavelength conversion substance that converts a wavelength of at least a portion of light from the light-emitting element 6. The light transmissive member 7 can be formed by using a light-transmissive resin material or an inorganic material such as a ceramic or glass. As the resin material, a thermosetting resin such as a silicone resin, a silicone-modified resin, an epoxy resin, an epoxy-modified resin, or a phenol resin can be used. In particular, a silicone resin or a modified resin thereof having high light resistance and heat resistance is preferable. As used herein, “light-transmissive” means that 60% or more of the light from the light-emitting element 6 is preferably transmitted. Further, a thermoplastic resin such as a polycarbonate resin, an acrylic resin, a methylpentene resin, or a polynorbornene resin can be used for the light transmissive member 7. Further, the light transmissive member 7 can contain a light diffusing substance in the resin described above. For example, the light transmissive member 7 can be a resin material, a ceramic, glass, or the like containing a wavelength conversion substance, a sintered body of a wavelength conversion substance, or the like. The light transmissive member 7 can be a multilayer member in which a resin layer is disposed on the upper-side surface of a formed body of a resin, a ceramic, glass, or the like.

Examples of a wavelength conversion substance contained in the light transmissive member 7 include yttrium aluminum garnet based phosphors (for example,(Y,Gd)₃(Al,Ga)₅O₁₂:Ce), lutetium aluminum garnet based phosphors (for example, Lu₃(Al,Ga)₅O₁₂:Ce), terbium aluminum garnet based phosphors (for example, Tb₃(Al,Ga)₅O₁₂:Ce), CCA based phosphors (for example, Ca₁₀(PO₄)₆Cl₂:Eu), SAE based phosphors (for example, Sr₄Al₁₄O₂₅:Eu), chlorosilicate based phosphors (for example, Ca₈MgSi₄O₁₆Cl₂:Eu), silicate based phosphors (for example, (Ba,Sr,Ca,Mg)₂SiO₄:Eu), oxynitride based phosphors such as β-SiAlON based phosphors (for example, (Si,Al)₃(O,N)₄:Eu) and α-SiAlON based phosphors (for example, Ca(Si,Al)₁₂(O,N)₁₆:Eu), nitride based phosphors such as LSN based phosphors (for example, (La,Y)₃Si₆N₁₁:Ce), BSESN based phosphors (for example, (Ba,Sr)₂Si₅N₈:Eu), SLA based phosphors (for example, SrLiAl₃N₄:Eu), CASN based phosphors (for example, CaAlSiN₃:Eu), and SCASN based phosphors (for example, (Sr,Ca)AlSiN₃:Eu), fluoride based phosphors such as KSF based phosphors (for example, K₂SiF₆:Mn), KSAF based phosphors (for example, K₂(Si₁₋ₓAlₓ)F₆₋ₓ:Mn, where x satisfies 0<x<1), and MGF based phosphors (for example, 3.5MgO·0.5MgF₂GeO₂:Mn), quantum dots having a Perovskite structure (for example, (Cs,FA,MA)(Pb,Sn)(F,Cl,Br,I)₃, where FA and MA represent formamidinium and methylammonium, respectively), II-VI quantum dots (for example, CdSe), III-V quantum dots (for example, InP), and quantum dots having a chalcopyrite structure (for example, (Ag,Cu)(In,Ga)(S,Se)₂). The wavelength conversion substances described above are particles. One of these wavelength conversion substances can be used alone, or two or more of these wavelength conversion substances can be used in combination.

The light-emitting device 200 uses a blue LED as the light-emitting element 6. The light transmissive member 7 contains a wavelength conversion substance that converts the wavelength of light emitted from the light-emitting element 6 into the wavelength of yellow light. Accordingly, the light-emitting device 200 can emit white light. As the light diffusing substance contained in the light transmissive member 7, titanium oxide, barium titanate, aluminum oxide, silicon oxide, or the like can be used.

### Light Reflecting Member 8

The light reflecting member 8 is a member having light reflectivity. The light reflecting member 8 is disposed so as to cover the upper surface 1a of the ceramic substrate 1 and the like of the mounting substrate 100 and cover the lateral surfaces of the light-emitting element 6 and the lateral surfaces of the light transmissive member 7. Further, the light reflecting member 8 is disposed so as to expose the light emitting surface 201. As an example, the light reflecting member 8 is also disposed between the lower surface of the light-emitting element 6 and the upper surface 1a of the ceramic substrate 1 in the mounting substrate 100.

The light reflecting member 8 preferably has a high reflectance in order to effectively utilize light from the light-emitting element 6. The color of the light reflecting member 8 is preferably white. The reflectance of the light reflecting member 8 is preferably, for example, 90% or more, and more preferably 94% or more at the wavelength of the light emitted from the light-emitting element 6.

As a resin used for the light reflecting member 8, a thermoplastic resin such as an acrylic resin, a polycarbonate resin, a cyclic polyolefin resin, a polyethylene terephthalate resin, a polyethylene naphthalate resin, or a polyester resin, or a thermosetting resin such as an epoxy resin or a silicone resin can be used. As a light diffusing material used for the light reflecting member 8, any known material such as titanium oxide, silicon oxide, aluminum oxide, zinc oxide, or glass, can be used.

### Pair of Electrodes 9

The pair of electrodes 9 are connected to the metal members 2 of the mounting substrate 100 via the metal films 21 by the electrically-conductive bonding material 10. One of the electrodes 9 is a p-electrode and the other is an n-electrode, and the p-electrode is disposed at a distance from the n-electrode so as not to be electrically short-circuited. In the illustrated example, the electrodes 9 are configured such that one p-electrode and one n-electrode are disposed at respective positions; however, one of the p-electrode or the n-electrode can be disposed at two positions and the other can be disposed at one position. The shortest distance between the electrodes 9 is preferably the same as the width of the upper surface 1a of the ceramic substrate 1, but can be smaller or larger than the width of the upper surface 1a. By setting the shortest distance between the electrodes 9 to be the same as the width of the upper surface 1a of the ceramic substrate 1, electricity and heat from the pair of electrodes 9 can be efficiently transferred to the metal members 2 and the bonding material 3. By setting the shortest distance between the electrodes 9 to be smaller than the width of the upper surface 1a of the ceramic substrate 1, the metal members 2 can be prevented from being short-circuited. By setting the shortest distance between the electrodes 9 to be larger than the width of the upper surface 1a of the ceramic substrate 1, the pair of electrodes 9 can be prevented from being short-circuited. Further, the area of the pair of electrodes 9 are preferably the same as the area of the upper surfaces 2a of the metal members 2 and of the upper surface 3a of the bonding material 3, but can be smaller or larger than the area of the upper surfaces 2a of the metal members 2 and of the upper surface 3a of the bonding material 3. By setting the area of the pair of electrodes 9 to be the same as the area of the upper surfaces 2a of the metal members 2 and of the upper surface 3a of the bonding material 3, a positional deviation between the light-emitting element 6 and the metal members 2 can be reduced. By setting the area of the pair of electrodes 9 to be smaller than the area of the upper surfaces 2a of the metal members 2 and of the upper surface 3a of the bonding material 3, electricity and heat from the pair of electrodes 9 can be efficiently transferred to the metal members 2 and the bonding material 3. By setting the area of the pair of electrodes 9 to be smaller than the area of the upper surfaces 2a of the metal members 2 and of the upper surface 3a of the bonding material 3, the size of the mounting substrate can be reduced.

### Electrically-Conductive Bonding Material 10

The electrically-conductive bonding material 10 electrically connects the pair of electrodes 9 to the metal members 2 of the mounting substrate 100. The electrically-conductive bonding material 10 can be disposed on the pair of electrode 9 side or on the metal member 2 side of the mounting substrate 100. The shape, the size, and the number of electrically-conductive bonding materials 10 can be appropriately set as long as the electrically-conductive bonding material 10 can be disposed within the ranges of the pair of electrodes 9. Further, the size of the electrically-conductive bonding material 10 can be appropriately adjusted according to the size of the light-emitting element 6, the required light emission output of the light-emitting element 6, and the like. For example, one electrically-conductive bonding material 10 can have a diameter of about several tens of μm to several hundreds of μm.

For example, the electrically-conductive bonding material 10 can be formed of at least one selected from the group consisting of, Au, Ag, Cu, Al, Sn, Pt, Zn, and Ni, or an alloy thereof, and can be formed of, for example, stud bumps known in the field. The stud bumps can be formed by a stud bump bonder, a wire bonding device, or the like. The electrically-conductive bonding material 10 can be formed by a method publicly known in the field, such as electrolytic plating, electroless plating, vapor deposition, or sputtering.

As an example, the electrically-conductive bonding material 10 is bonded via the metal films 21. Examples of the metal films 21 that can be used include: solders such as tin-bismuth-based solder, tin-copper-based solder, tin-silver-based solder, and gold-tin-based solder; eutectic alloys such as an alloy containing Au and Sn as main components, an alloy containing Au and Si as main components, and an alloy containing Au and Ge as main components; paste materials such as Au, Ag, and palladium; anisotropic conductive materials such as ACP and ACF; brazing materials of low-melting-point metals; electrically-conductive adhesives using a combination of these materials; and electrically-conductive composite adhesives.

In the light-emitting device 200, one light-emitting element 6 is used as one unit to control brightness and turning on and off. However, one or more light-emitting elements 6 can be included in one unit. For example, four light-emitting elements 6 arranged in one row and four columns or in two rows and two columns, or nine light-emitting elements 6 arranged in three rows and three columns can be used as one unit, and the number of light-emitting elements 6 is not limited.

### Method of Manufacturing Light-Emitting Device 200

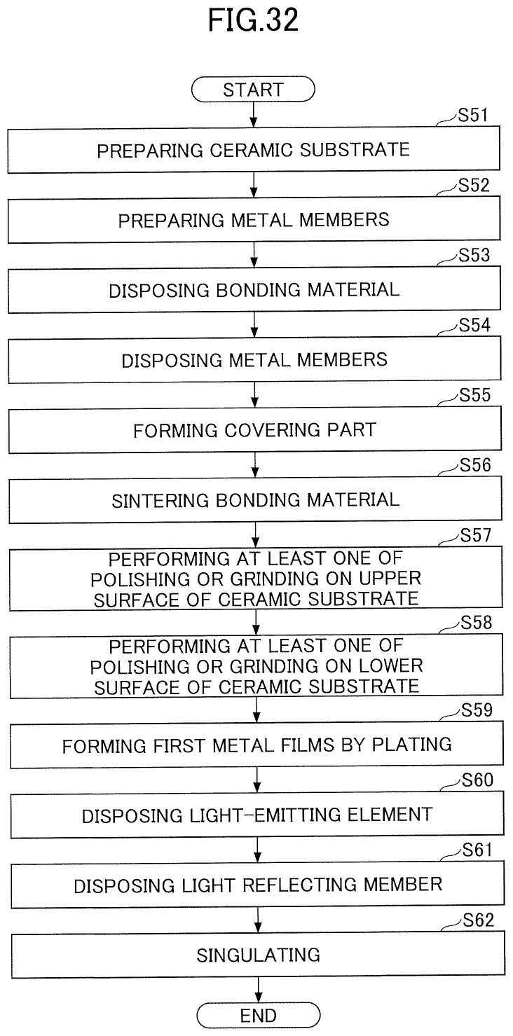

A method of manufacturing a light-emitting device 200 will be described with reference to FIG. 32. FIG. 32 is a flowchart illustrating an example of the method of manufacturing the light-emitting device 200.

The method of manufacturing the light-emitting device 200 includes preparing a ceramic substrate 1 having two or more through holes 11 or recesses (S51), and disposing a bonding material 3 in each of the through holes 11 or the recesses of the ceramic substrate 1 (S53). The method of manufacturing the light-emitting device 200 further includes disposing metal members 2 in the respective through holes 11 or the recesses of the ceramic substrate 1 (S54), and sintering the bonding material 3 disposed in each of the through holes 11 or the recesses of the ceramic substrate 1 (S56). The method of manufacturing the light-emitting device 200 further includes disposing a light-emitting element 6 such that the light-emitting element 6 is electrically connected to each of the metal members 2 in the ceramic substrate 1 in which the bonding material 3 is sintered (S60).

The method of manufacturing the light-emitting device 200 illustrated in FIG. 32 includes preparing the metal members 2 (S52), and forming an electrically-conductive covering part 5 so as to cover the bonding material 3 and at least one of the upper surface or the lower surface of the ceramic substrate 1 after the bonding material 3 is disposed yet before the bonding material 3 is sintered (S55). The method of manufacturing the light-emitting device 200 illustrated in FIG. 32 further includes performing at least one of polishing or grinding on the covering part 5 and the upper surface of the ceramic substrate 1 after the bonding material 3 is sintered so as to expose the metal members 2 (S57). The method of manufacturing the light-emitting device 200 illustrated in FIG. 32 further includes performing at least one of polishing or grinding on the covering part 5 and the lower surface of the ceramic substrate 1 after the bonding material 3 is sintered so as to expose the metal members 2 (S58). The method of manufacturing the light-emitting device 200 illustrated in FIG. 28 further includes forming, by plating, first metal films 211 on upper surfaces 2a of the metal members 2 of the ceramic substrate 1 subjected to at least one of polishing or grinding (S59), and disposing a light reflecting member 8 on the light-emitting element 6 disposed on the metal members 2 (S61). Further, in the example illustrated in FIG. 32, the light-emitting device 200 includes a plurality of sets each including the ceramic substrate 1 and the metal members 2, and the method of manufacturing the light-emitting device 200 includes singulating the plurality of sets (S62).

S41 to S48 in the method of manufacturing the light-emitting device 200 illustrated in FIG. 32 are the same as S11 to S18 in the method of manufacturing the mounting substrate 100 according to the first embodiment.

S59: Forming First Metal films 211 by Plating

In S59, the first metal films 211 are formed by plating on the upper surfaces 2a of the metal members 2 of the ceramic substrate 1 subjected to at least one of polishing or grinding in S58.

### S60: Disposing Light-Emitting Element 6

In S60, the light-emitting element 6 is disposed so as to be electrically connected to each of the metal members 2 in the ceramic substrate 1 in which the bonding material 3 is sintered. In S60, a pair of electrodes 9 are connected to the first metal films 211 formed on the upper surfaces 2a of the metal members 2 by using an electrically-conductive bonding material 10. A light transmissive member 7 is disposed on the light-emitting element 6 in advance. When the light-transmissive member 7 is bonded to the light-emitting element 6, a light-transmissive bonding material can be used.

### S61: Disposing Light-Reflecting Member 8

In S61, the light reflecting member 8 is disposed so as to cover the upper surface 1a of the ceramic substrate 1 of the mounting substrate 100, the lateral surfaces of the light-emitting element 6, and the lateral surfaces the light transmissive member 7. In S61, the light reflecting member 8 is disposed so as to surround the light-emitting element 6 and expose the upper surface of the light transmissive member 7 that serves as a light emitting surface 201 of the light-emitting device 200. The light reflecting member 8 is disposed so as to have a rectangular shape in a plan view.

### S62: Singulating

In S62, a plurality of light-emitting devices 200 are singulated. The method of manufacturing the light-emitting device 200 includes singulating the plurality of light-emitting devices 200, and thus a large number of light-emitting devices 200 can be obtained from one ceramic substrate 1. Therefore, the manufacturing efficiency of the light-emitting device 200 can be increased. In S62, the plurality of light-emitting devices 200 can be singulated by cutting between adjacent light-emitting devices 200 of the plurality of light-emitting devices 200. As a cutting method of singulating the plurality of light-emitting devices, for example, a method using a rotation blade having a disk shape, a ultrasonic cutter, laser light irradiation, a blade, or the like can be used. By singulating the plurality of light-emitting devices (S62), a lateral surface 2d of each of the metal members 2, exposed through the ceramic substrate 1, is coplanar with a lateral surface of the ceramic substrate 1.

### Sixth Embodiment

### Configuration of Light-Emitting Device According to Sixth Embodiment

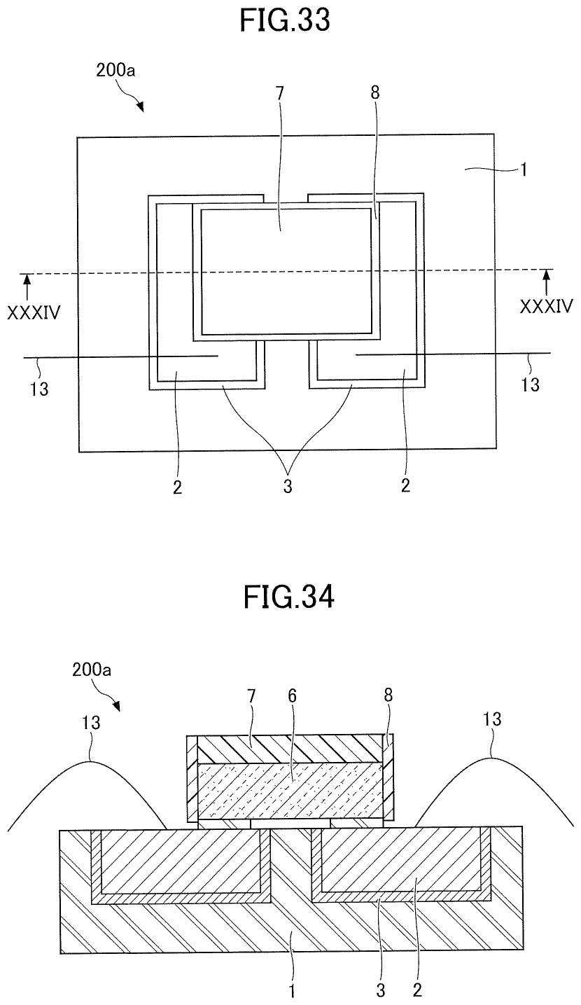

A light-emitting device according to a sixth embodiment will be described with reference to FIG. 33 and FIG. 34. FIG. 33 is a schematic top view illustrating an example of a light-emitting device 200a according to the sixth embodiment. FIG. 34 is a schematic cross-sectional view taken through line XXXIV-XXXIV of FIG. 33.

The light-emitting device 200a differs from the light-emitting device 200 according to the fifth embodiment mainly in that the light-emitting device 200a includes the mounting substrate 100c according to the fourth embodiment and a pair of wires 13 electrically connected to the metal members 2.

By including the mounting substrate 100c, the light-emitting device 200a can reduce the movement of an electrically-conductive bonding material disposed on the metal members 2. This enables self-alignment of an electronic component disposed on the metal and control of the thicknesses of the electrically-conductive bonding material. In the present embodiment, by enabling self-alignment of the electronic component disposed on the metal and control of the thicknesses of the electrically-conductive bonding material, the light-emitting element 6 can be easily disposed on the mounting substrate through which the metal is exposed, and thus the light-emitting device 200a can be easily manufactured. Further, because the ceramic substrate 1 has the recesses 12, an effect of reducing leakage of the bonding material 3 can be obtained

Although specific embodiments of the present invention have been described above, the embodiments are presented as examples, and the present invention is not limited to the embodiments. The embodiments described above can be implemented in various other forms, and various combinations, omissions, replacements, additions, and modifications can be made thereto without departing from the scope of the present invention. The embodiments and modifications thereof are included in the scope and spirit of the present invention, and are included in the present invention described in the claims and the scope of equivalents thereof.

The mounting substrates and the light-emitting devices according to the embodiments of the present disclosure can be utilized as light sources for adaptive driving beam headlights. In addition, the mounting substrates and the light-emitting devices according to the embodiments of the present disclosure can be utilized in liquid crystal display backlights, various lighting fixtures, large displays, various display devices for advertising and destination signs, image pickup devices in digital video cameras, facsimiles, copiers, and scanners, as well as projectors, and the like.

According to one embodiment of the preset disclosure, a mounting substrate or a light-emitting device, in which an electronic component can be easily disposed on the mounting substrate through which a metal is exposed, can be provided. According to one embodiment of the present disclosure, a mounting substrate having a high heat dissipation property or a light-emitting device including the mounting substrate having a high heat dissipation property can be provided.

1. A mounting substrate comprising:
a ceramic substrate having two or more through holes;
metal members disposed in respective through holes of the two or more through holes; and
a bonding material disposed between the ceramic substrate and each of the metal members in the two or more through holes, the bonding material being configured to bond the ceramic substrate to the metal members; wherein
a portion of an upper surface of each of the metal members, a portion of a lower surface of each of the metal members, and a portion of lateral surfaces of each of the metal members are exposed through the ceramic substrate,
the portion of the lateral surfaces of each of the metal members and the portion of the lower surface of each of the metal members, which are exposed through the ceramic substrate, are continuous with each other,
the portion of the lateral surfaces of each of the metal members, which is exposed through the ceramic substrate, is coplanar with a lateral surface of the ceramic substrate, and
the ceramic substrate is disposed so as to surround an outer periphery of each of the metal members when viewed in a top view.

2. The mounting substrate according to claim 1, wherein the bonding material is an active metal brazing material.

3. The mounting substrate according to claim 1, further comprising:
a metal film disposed on the upper surface of each of the metal members.

4. The mounting substrate according to claim 3, wherein the metal film extends from the upper surface of each of the metal members to a portion of an upper surface of the ceramic substrate.

5. The mounting substrate according to claim 1, wherein the portion of the lateral surfaces of each of the metal members is exposed through the ceramic substrate.

6. The mounting substrate according to claim 5, further comprising:
a stepped surface connected to an upper end of the portion of the lateral surfaces of each of the metal members and located below the upper surface of each of the metal members, wherein
a portion of the ceramic substrate is disposed on the stepped surface.

7. A mounting substrate comprising:
a ceramic substrate having two or more recesses formed in an upper surface;
metal members disposed in respective recesses of the two or more recesses; and
a bonding material disposed between the ceramic substrate and each of the metal members in the two or more recesses, the bonding material being configured to bond the ceramic substrate to the metal members; wherein
an upper surface of each of the metal members is exposed through the ceramic substrate, and
a lower surface of each of the metal members faces a flat surface defining a part of a corresponding one of the two or more recesses of the ceramic substrate.

8. A light-emitting device comprising:
the mounting substrate of claim 1; and
a light-emitting element disposed so as to be electrically connected to the metal members.

9. A method of manufacturing a mounting substrate, the method comprising:
preparing a ceramic substrate having two or more through holes or two or more recesses;
disposing a bonding material in the two or more through holes or in the two or more recesses;
disposing metal members in respective through holes of the two or more through holes or in respective recesses of the two or more recesses; and
sintering the bonding material disposed in the two or more through holes or in the two or more recesses.

10. The method of manufacturing the mounting substrate according to claim 9, further comprising:
forming an electrically-conductive covering part so as to cover the bonding material and at least one of an upper surface of the ceramic substrate or a lower surface of the ceramic substrate after the bonding material is disposed yet before the bonding material is sintered.

11. The method of manufacturing the mounting substrate according to claim 10, further comprising:
performing at least one of polishing or grinding on the electrically-conductive covering part and the upper surface of the ceramic substrate after the bonding material is sintered, so as to expose the metal members.

12. The method of manufacturing the mounting substrate according to claim 11, further comprising:
performing at least one of polishing or grinding on the electrically-conductive covering part and the lower surface of the ceramic substrate after the bonding material is sintered, so as to expose the metal members.

13. The method of manufacturing the mounting substrate according to claim 11, further comprising:
forming, by plating, a first metal film on an upper surface of each of the metal members in the ceramic substrate subjected to at least one of the polishing or the grinding.

14. The method of manufacturing the mounting substrate according to claim 11, further comprising:
forming, by sputtering, a second metal film on the upper surface of the ceramic substrate subjected to at least one of the polishing or the grinding.

15. The method of manufacturing the mounting substrate according to claim 14, further comprising:
forming, by plating, a first metal film on the second metal film formed by the sputtering.

16. The method of manufacturing the mounting substrate according to claim 9, wherein
the mounting substrate includes a plurality of sets each including the ceramic substrate and the metal members, and
the method further includes singulating the plurality of sets.

17. A method of manufacturing a light-emitting device, the method comprising:
preparing a ceramic substrate having two or more through holes or two or more recesses;
disposing a bonding material in the two or more through holes or in the two or more recesses;
disposing metal members in respective through holes of the two or more through holes or in respective recesses of the two or more recesses;
sintering the bonding material disposed in the two or more through holes or in the two or more recesses; and
disposing a light-emitting element such that the light-emitting element is electrically connected to the metal members in the ceramic substrate in which the bonding material is sintered.
